(19) United States
(12) Patent Application Publication
(10) Pub. No.: US 2025/0113584 A1
(43) Pub. Date: Apr. 3, 2025

(54) SEMICONDUCTOR STRUCTURE AND PREPARATION METHOD THEREFOR

(71) Applicant: CXMT CORPORATION, Hefei (CN)

(72) Inventor: TIEH-CHIANG WU, Hefei (CN)

(21) Appl. No.: 18/949,954

(22) Filed: Nov. 15, 2024

Related U.S. Application Data
(63) Continuation of application No. PCT/CN2023/088369, filed on Apr. 14, 2023.

(30) Foreign Application Priority Data
Nov. 10, 2022 (CN) 202211404804.9

(51) Int. Cl. H10D 64/23; H10D 64/01

(52) U.S. Cl. CPC H10D 64/258; H10D 64/01

(57) ABSTRACT

The present disclosure relates to a semiconductor structure and a preparation method therefor. The semiconductor structure includes a base, a dielectric layer, and conductive plugs. The dielectric layer is located on the base and is internally provided with multiple contact holes arranged in a first direction. The conductive plug is located in the contact hole, and includes a connection section and a recessed section. The connection section is configured for conductive connection, the recessed section is connected to the connection section in a second direction and recessed downwards relative to the connection section, and the second direction intersects the first direction.

### CROSS-REFERENCE TO RELATED APPLICATIONS

The present disclosure is a continuation of PCT/CN2023/088369, filed on Apr. 14, 2023, which claims priority to Chinese Patent Application No. 2022114048049, filed with the China National Intellectual Property Administration on Nov. 10, 2022 and entitled “SEMICONDUCTOR STRUCTURE AND PREPARATION METHOD THEREFOR”, which is incorporated herein by reference in its entirety.

### TECHNICAL FIELD

The present disclosure relates to the field of integrated circuit technologies, and in particular, to a semiconductor structure and a preparation method therefor.

### BACKGROUND

In semiconductor structures, signal transmission is often implemented with conductive plugs. Conductive plugs may be formed within contact holes in a dielectric layer to implement connection between semiconductor devices and the outside.

However, when multiple conductive plugs are disposed side by side, a relatively large parasitic capacitance is generated between the conductive plugs, affecting component performance.

### SUMMARY

According to various embodiments of the present disclosure, a semiconductor structure and a preparation method therefor are provided.

According to various embodiments of the present disclosure, a semiconductor structure is provided, including:
a base;
a dielectric layer being located on the base and internally provided with multiple contact holes arranged in a first direction; and
multiple conductive plugs arranged in the first direction, the conductive plug being located in the contact hole and including a connection section and a recessed section, the connection section being configured for conductive connection, the recessed section being connected to the connection section in a second direction and recessed downwards relative to the connection section, and the second direction intersecting the first direction.

According to various embodiments of the present disclosure, a preparation method for a semiconductor structure is further provided, including the following steps:
a base is provided, a dielectric layer being formed on the base;
multiple contact holes arranged in a first direction are formed in the dielectric layer; and
a conductive plug is formed in each of the contact holes, the conductive plug including a connection section and a recessed section, the connection section being configured for conductive connection, the recessed section being connected to the connection section in a second direction and recessed downwards relative to the connection section, and the second direction intersecting the first direction.

The details of one or more embodiments of the present disclosure are set forth in the following accompanying drawings and description. Other features, objectives, and advantages of the present disclosure will become apparent from the specification, drawings, and claims.

### BRIEF DESCRIPTION OF DRAWINGS

To describe the technical solutions in the embodiments of the present disclosure or the conventional technologies more clearly, the following briefly describes the accompanying drawings required for describing the embodiments or the conventional technologies. Clearly, the accompanying drawings in the following description show merely some embodiments of the present disclosure, and a person of ordinary skill in the art may still derive other drawings from these accompanying drawings without creative efforts.

FIG. 1 is a schematic diagram of a top-view structure of a semiconductor structure according to an embodiment;

FIG. 2 is a schematic cross-sectional diagram of the semiconductor structure shown in FIG. 1 in an AA′ direction;

FIG. 3 is a schematic cross-sectional diagram of the semiconductor structure shown in FIG. 1 in a BB′ direction;

FIG. 4 is a schematic cross-sectional diagram of the semiconductor structure shown in FIG. 1 in a CC′ direction;

FIG. 5 is a flowchart of a preparation method for a semiconductor structure; and

FIG. 6 to FIG. 11 are schematic cross-sectional diagrams of structures obtained in a semiconductor structure preparation process shown in FIG. 1, FIG. 6 and FIG. 7 being schematic cross-sectional diagrams in the AA′ direction, and FIG. 8 to FIG. 11 being schematic cross-sectional diagrams in the BB′ direction.

To better describe and illustrate the embodiments and/or examples of the invention disclosed herein, reference may be made to one or more of the accompanying drawings. Additional details or examples used to describe the accompanying drawings should not be construed as limitations on the scope of any one of the disclosed invention, the currently described embodiments and/or examples, and the optimal modes for the currently understood invention.

### DESCRIPTION OF EMBODIMENTS

For case of understanding of the present disclosure, a more comprehensive description of the present disclosure is provided below with reference to related accompanying drawings. A preferred embodiment of the present disclosure is provided in the accompanying drawings. However, the present disclosure may be implemented in many different forms, and is not limited to the embodiments described herein. Instead, the purpose of providing these embodiments is to make the content of the present disclosure more thorough and comprehensive.

Unless otherwise defined, all technical and scientific terms utilized in the specification have meanings the same as those commonly understood by a person skilled in the technical field of the present disclosure. The terms utilized in the specification of the present disclosure are merely intended to describe specific embodiments, and are not intended to limit the present disclosure

It should be understood that, an element or a layer may be directly on, adjacent to, connected to, or coupled to another element or layer or there may be an intermediate element or layer when the element or the layer is referred to as “on”, “adjacent to”, “connected to”, or “coupled to” the another element or layer. Instead, there is no intermediate element or layer when an element is referred to as “directly on”, “directly adjacent to”, “directly connected to”, or “directly coupled to” another element or layer. It should be understood that, although the terms “first”, “second”, “third”, and the like may be adopted to describe various elements, components, regions, layers, doping types, and/or portions, these elements, components, regions, layers, doping types, and/or portions shall not be limited by these terms. These terms are merely adopted to distinguish one element, component, region, layer, doping type, or portion from another element, component, region, layer, doping type, or portion. Therefore, a first element, component, region, layer, doping type, or portion discussed below may be represented as a second element, component, region, layer, or portion without departing from the teachings of the present disclosure.

Spatial relationship terms, e.g., “under”, “below”, “underlying”, “beneath”, “over”, “above”, and the like may be utilized herein to describe a relationship between one element or feature shown in the figures and another component or feature. It should be understood that, in addition to the orientations shown in the figures, the spatial relationship terms further include different orientations of devices in use and operation. An element or a feature described as “below another element” is oriented to be “above” the another element or feature, e.g., if the devices in the accompanying drawings are flipped. Therefore, the example term “below” may include orientations of being above and being below. In addition, the devices may alternatively be otherwise oriented (rotated by 90 degrees or oriented in another manner), and the spatial descriptors utilized herein are interpreted accordingly.

As utilized herein, the singular forms of “a”, “an”, and “the” are also intended to include plural forms unless otherwise clearly specified in the context. It should also be understood that, the presence of the feature, integer, step, operation, element, and/or component can be determined without ruling out the presence or addition of one or more other features, integers, steps, operations, elements, components, and/or groups when the term “constitute” and/or the term “include” are/is utilized in the specification. Moreover, as utilized herein, the term “and/or” includes any and all combinations of the related items listed.

Related structures in the embodiments of the present disclosure shall not be limited to specific shapes of the structures shown in the accompanying drawings of the specification, but include shape deviations caused by, e.g., manufacturing technologies.

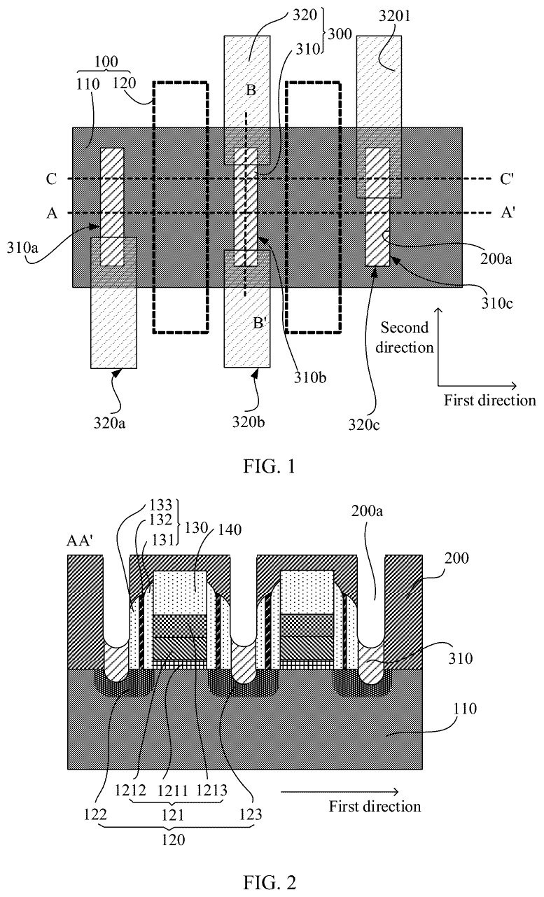

In an embodiment, referring to FIG. 1 to FIG. 4, a semiconductor structure is provided, including a base 100, a dielectric layer 200, and multiple conductive plugs 310.

The base 100 may include a semiconductor substrate 110, and semiconductor devices, circuit structures, and/or the like formed on the semiconductor substrate.

The semiconductor substrate 110 may include a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate, or another III/V semiconductor substrate or II/VI semiconductor substrate, or the like. Alternatively, in another example, the semiconductor substrate 110 may include a silicon on insulator (SOI) substrate, a silicon germanium on insulator substrate, or the like.

The material of the dielectric layer 200 may include but is not limited to a silicon oxide layer (SiO₂), silicon nitride (Si₃N₄), aluminum oxide (Al₂O₃), or silicon nitride oxide (SiON).

The dielectric layer 200 is located on the base 100, and is internally provided with multiple contact holes 200a arranged in a first direction. Portions of the base 100 that need to be conductively connected are exposed by the contact holes 200a.

As an example, the conductive plug 310 may include a metal plug. The material of the metal plug may include but is not limited to tungsten. In addition, a metal diffusion barrier layer (not shown) may be further provided between the conductive plug 310 and the inner wall of the contact hole 200a, so as to prevent metal in the metal plug from diffusing into the dielectric layer 200. Specifically, the material of the metal diffusion barrier layer may be, e.g., titanium nitride and/or titanium.

The conductive plug 310 is located in the contact hole 200a, and therefore the multiple conductive plugs 310 are also arranged in the first direction. As an example, the conductive plug 310 may extend in a second direction to form a long plug. The second direction intersects the first direction. For example, the second direction may be perpendicular to the first direction. Certainly, the second direction may be not perpendicular to the first direction, and this is not limited herein.

The contact hole 200a is fully filled by a conventional conductive plug 310. Therefore, a relatively high parasitic capacitance is formed between the conductive plugs (especially long plugs).

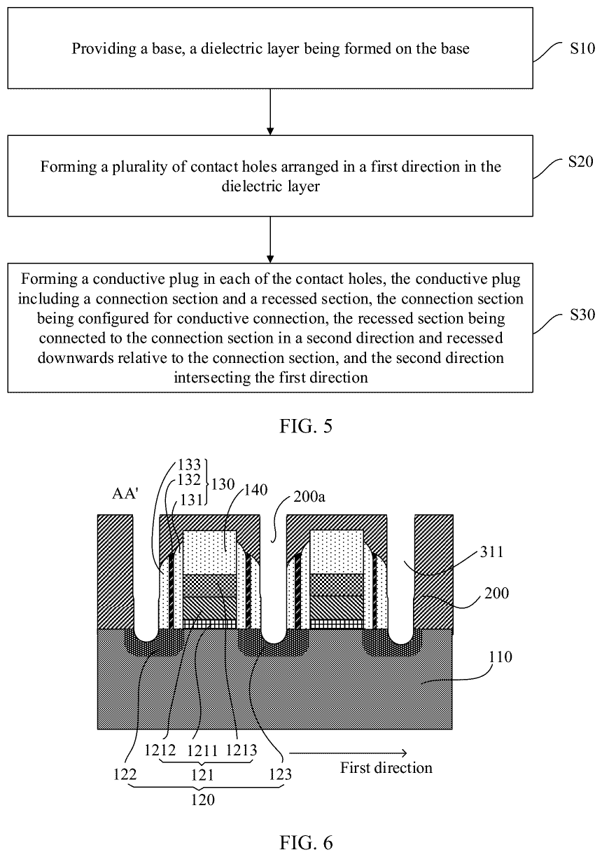

In this embodiment, referring to FIG. 1 and FIG. 3, the conductive plug includes a connection section 3002 and a recessed section 3001. The connection section 3002 is configured for conductive connection. The recessed section 3001 is connected to the connection section 3002 in the second direction and recessed downwards relative to the connection section. In this case, due to the presence of the recessed section 3001, a direct-facing area between the conductive plugs 310 can be effectively reduced, thereby effectively reducing the parasitic capacitance between the conductive plugs 310.

In an embodiment, the connection sections 3002 of adjacent conductive plugs 310 are at least partially staggered. In this case, the direct-facing area between the adjacent conductive plugs 310 can be further reduced, thereby further reducing the parasitic capacitance between the adjacent conductive plugs 310.

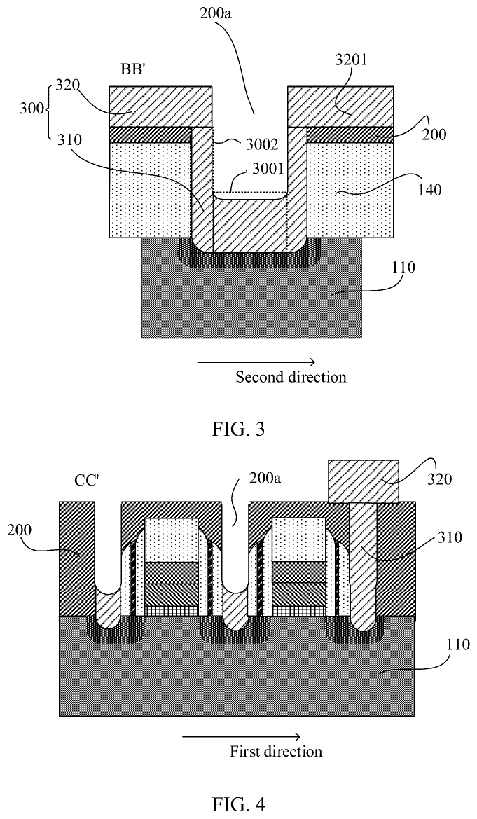

In an embodiment, the base 100 further includes a transistor structure 120. Referring to FIG. 2, the transistor structure 120 includes a gate structure 121, a source region 122, and a drain region 123.

The gate structure 121 may specifically include a gate dielectric layer 1211, a first gate layer 1212, and a second gate layer 1213. The gate dielectric layer 1211 may include but is not limited to a gate oxide layer. The first gate layer 1212 may include but is not limited to a polysilicon layer. The second gate layer 1213 may include but is not limited to a metal layer.

An insulation protection layer 140 may be formed on the top of the gate structure 121 to protect the gate structure 121. The insulation protection layer 140 may be an oxide layer, a nitride layer, a nitride oxide layer, or the like.

The source region 122 and the drain region 123 are located on both sides of the gate structure 121. Moreover, a side-wall structure 130 may further be formed on the side wall of the gate structure 121, so as to provide side-wall protection for the gate structure 121 while doping the semiconductor substrate 110 to form the source region 122 and the drain region 123. The side-wall structure 130 may include, e.g., a first oxide layer 131, a nitride layer 132, and a second oxide layer 133.

The transistor structure 120 is covered by the dielectric layer 200. The contact hole 200a extends to the source region 122 and/or the drain region 123 of the transistor structure. In this case, a source signal and/or a drain signal are/is transmitted by the source region 122 and/or the drain region 123 of the transistor structure 120 through the conductive plug 310 located in the contact hole 200a.

In this case, since the gate structure 121 also includes a conductive layer (e.g., the first gate layer 1212 or the second gate layer 1213), and the conductive layer may include a metal conductive layer (e.g., the second gate layer 1213), a coupling parasitic capacitance is prone to be generated by the gate structure 121 and the conductive plug 310, affecting device performance.

In this embodiment, referring to FIG. 2 to FIG. 4, the recessed section 3001 of the conductive plug 310 is recessed downwards to a height less than the height of the gate structure 121.

As an example, the recessed section 3001 of the conductive plug 310 may be recessed downwards such that the upper surface is lower than the upper surface of the second gate layer 1213 when the first gate layer 1212 includes a polysilicon layer and the second gate layer 1213 includes a metal layer.

In this case, the parasitic capacitance between the conductive plugs 310 can be effectively reduced, so that the parasitic capacitance between the gate structure 121 and the conductive plug 310 can also be slightly reduced, thereby ensuring device performance.

In an embodiment, the shape of the conductive plug 310 includes an L-shape and/or a U-shape. The connection section 3002 is connected to only one side of the recessed section 3001 when the conductive plug 310 is L-shaped. The connection section 3002 is connected to both sides of the recessed section 3001 when the conductive plug 310 is U-shaped.

In an embodiment, referring to FIG. 1 and FIG. 3, the semiconductor structure further includes multiple wiring structures 320. The wiring structure 320 is located on the surface of the dielectric layer 200 and extends in the second direction. In addition, the wiring structure 320 is connected to the connection section 3002 of the conductive plug 310.

The multiple wiring structures 320 are also arranged in the first direction, so that the connection sections 3002 of the conductive plugs 310 arranged in the first direction may be respectively connected, so as to supply power to the conductive plugs respectively. Different wiring structures 320 may be connected to different conductive plugs 310. A conductive line 300 in the semiconductor structure may be jointly formed by one wiring structure 320 and a conductive plug 310 connected thereto. One signal may be transmitted by one conductive line 300.

As an example, the width of the wiring structure 320 may be greater than the width of the conductive plug 310, so that the conductive plug 310 is provided with better conductivity.

The wiring structure 320 includes at least one wiring portion 3201, and the wiring portion 3201 is connected to an end of the conductive plug 310. Specifically, multiple wiring portions 3201 are disposed at intervals and are connected through the conductive plugs 310 in the contact holes 200a when the wiring structure 320 include the multiple wiring portions 3201.

The material of the wiring structure 320 may be the same as or different from the material of the conductive plug 310.

As an example, the wiring structure 320 may include a metal wiring. The material of the conductive plug 310 may include but is not limited to metal materials such as Co, Ni, Ti, W, Cu, and Al.

In an embodiment, referring to FIG. 1, adjacent wiring structures 320 are at least partially staggered.

In this case, the adjacent wiring structures 320 are not exactly opposite to each other, thereby effectively reducing a parasitic capacitance between the adjacent wiring structures 320. In this case, both the parasitic capacitance between the conductive plugs 310 of adjacent conductive lines 300 and the parasitic capacitance between the wiring structures 320 are effectively reduced, so that mutual interference between signals transmitted by different conductive lines 300 is effectively reduced.

In an embodiment, the wiring structure 320 may include a first wiring 320a, a second wiring 320b, and a third wiring 320c sequentially arranged in the first direction. The first wiring 320a, the second wiring 320b, and the third wiring 320c are disposed at intervals. The second wiring 320b is located between the first wiring 320a and the third wiring 320c.

Accordingly, the conductive plug 310 includes an L-shaped first plug 310a, a U-shaped second plug 310b, and an L-shaped third plug 310c sequentially arranged in the first direction.

In the second direction, the second plug 310b is connected to the second wirings 320b at both ends, the first plug 310a is connected to the first wiring 320a at one end, and the third plug 310c is connected to the third wiring 320c at one end.

In this case, the second wiring 320b connected to one end of the second plug 310b is opposite to the first wiring 320a connected to one end of the first plug 310a. The other end of the first plug 310a is not connected to the first wiring 320a. Therefore, the second wiring 320b connected to the other end of the second plug 310b is not opposite to the first wiring 320a.

Therefore, the second wiring 320b connected to the second plug 310b is not exactly opposite to the first wiring 320a connected to the first plug 310a, thereby reducing a parasitic capacitance therebetween.

Similarly, the second wiring 320b connected to the second plug 310b is not exactly opposite to the third wiring 320c connected to the third plug 310c, thereby reducing a parasitic capacitance therebetween.

In addition, as an example, the first plug 310a and the third plug 310c may be further connected to the wiring structures 320 at opposite ends.

Specifically, for example, referring to FIG. 1, both the upper end and the lower end of the second plug 310b are connected to the second wiring 320b. Moreover, the lower end of the first plug 310a is connected to the first wiring 320a, whereas the upper end thereof is not connected to the first wiring 320a. The upper end of the third plug 310c is connected to the third wiring 320c, whereas the lower end thereof is not connected to the third wiring 320c.

In this case, wiring portions 3201 of any two of the second wiring 320b, the first wiring 320a, and the third wiring 320c are at least partially staggered, thereby effectively reducing the parasitic capacitance between the wiring structures 320. The wiring portions 3201 of the first wiring 320a and the third wiring 320c are totally staggered, so that parasitic capacitances between the second wiring 320b and the first wiring 320a and the third wiring 320c on both sides thereof are uniformly consistent.

Moreover, as an example, a contact area S1 between the first plug 310a and the first wiring 320a connected thereto at one end may be set to be equal to a contact area S2 between the second plug 310b and the second wiring 320b connected thereto at both ends.

In this case, R1 is the same as R2 assuming that a contact resistance between the first plug 310a and the first wiring 320a connected thereto at one end is R1, and a contact resistance between the second plug 310b and the second wiring 320b connected thereto at both ends is R2.

Alternatively, as an example, a contact area S3 between the third plug 310c and the third wiring 320c connected thereto at one end may be set to be equal to a contact area S2 between the second plug 310b and the second wiring 320b connected thereto at both ends.

In this case, R3 is the same as R2 assuming that a contact resistance between the third plug 310c and the third wiring 320c connected thereto at one end is R3.

Certainly, S1, S2, and S3 may be set to be the same. In this case, R1, R2, and R3 are the same, so that synchronization performance of signals transmitted by the wiring structures 320 can be improved.

Alternatively, in some cases, a difference between any two of S1, S2, and S3 may be set to be less than a preset difference, so that S1 and S2 are close to S3, and synchronization performance of the signals transmitted by the wiring structures 320 is relatively good. The preset difference may be set according to an actual requirement.

In another embodiment, implementation may be achieved in another manner, so that adjacent wiring structures 320 are at least partially staggered. For example, the second plug 310b, the first plug 310a, and the third plug 310c may all be disposed as L-shaped conductive plugs. In the second direction, the second plug 310b, the first plug 310a, and the third plug 310c are all connected to the wiring structures 320 at one end. In addition, the second plug 310b and the other two conductive plugs (the first plug 310a and the third plug 310c) are connected to the wiring structures 320 at opposite ends.

Specifically, the upper end of the second plug 310b may be connected to the second wiring 320b, the lower end of the first plug 310a may be connected to the first wiring 320a, and the lower end of the third plug 310c may be connected to the third wiring 320c.

In this case, the contact area S2 between the second plug 310b and the second wiring 320b, the contact area S1 between the first plug 310a and the first wiring 320a, and the contact area S3 between the third plug 310c and the third wiring 320c may also be set to be the same or similar.

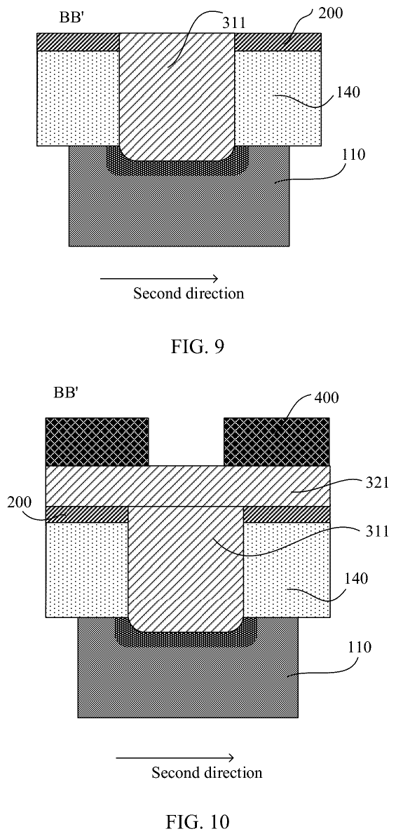

In an embodiment, referring to FIG. 5, a preparation method for a semiconductor structure is further provided, including the following steps:

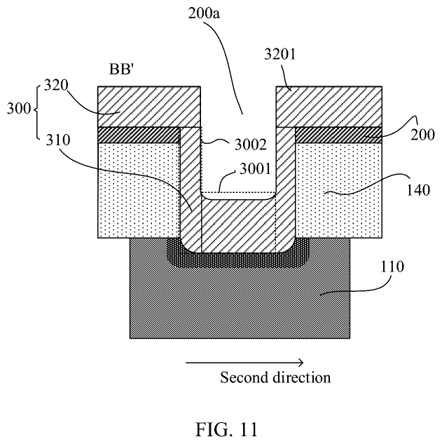

In the step of S10, referring to FIG. 6, a base 100 is provided, and a dielectric layer 200 is formed on the base 100.

In the step of S20, referring to FIG. 6, multiple contact holes 200a arranged in a first direction are formed in the dielectric layer 200.

In the step of S30, referring to FIG. 11 and FIG. 1, a conductive plug 310 is formed in each contact hole 200a. The conductive plug includes a connection section 3002 and a recessed section 3001. The connection section 3002 is configured for conductive connection. The recessed section 3001 is connected to the connection section 3002 in a second direction and recessed downwards relative to the connection section. The second direction intersects the first direction.

In the step of S10, the base 100 may include a semiconductor substrate 110, and semiconductor devices, circuit structures, and/or the like formed on the semiconductor substrate.

The semiconductor substrate 110 may include a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate, or another III/V semiconductor substrate or II/VI semiconductor substrate, or the like. Alternatively, for another example, the semiconductor substrate 110 may include a silicon on insulator (SOI) substrate, a silicon germanium on insulator substrate, or the like.

The dielectric layer 200 may be formed on the base 100 with a deposition process. Specifically, the deposition process may include but is not limited to one or more of processes such as a Chemical Vapor Deposition (CVD) process, an Atomic Layer Deposition (ALD) process, a High Density Plasma (HDP) process, a Plasma Enhanced Chemical Vapor Deposition (PECVD) process, and a Spin-on Dielectric (SOD) process.

The material of the dielectric layer 200 may include but is not limited to a silicon oxide layer (SiO₂), a silicon nitride layer (Si₃N₄), aluminum oxide (Al₂O₃), or a silicon nitride oxide layer (SiON).

In the step of S20, each contact hole 200a in the dielectric layer 200 may be formed with a dry etching process or the like.

Specifically, a patterned mask layer (not shown) may be first formed on the surface of the dielectric layer 200. The dielectric layer 200 is then etched based on the patterned mask layer, thereby forming each contact hole 200a. The contact hole 200a may be, e.g., a long-strip-shaped contact hole, so that the resistance of the conductive plug 310 can be effectively reduced. Certainly, the contact hole 200a may also be in another shape. Specifically, the contact hole 200a may be disposed according to a requirement, and this is not limited in detail herein.

In the step of S30, referring to FIG. 11 and FIG. 1, the conductive plugs 310 formed in the contact holes 200a are disposed at intervals in the first direction.

Moreover, as an example, the conductive plug 310 may extend in the second direction to form a long plug. The second direction intersects the first direction. For example, the second direction may be perpendicular to the first direction. Certainly, the second direction may be not perpendicular to the first direction, and this is not limited herein.

The contact hole 200a is fully filled by a conventional conductive plug 310. Therefore, a relatively high parasitic capacitance is formed between the conductive plugs (especially long plugs).

In this embodiment, referring to FIG. 1 and FIG. 11, the conductive plug includes the connection section 3002 and the recessed section 3001. The connection section 3002 is configured for conductive connection. The recessed section 3001 is connected to the connection section 3002 in the second direction and recessed downwards relative to the connection section. In this case, due to the presence of the recessed section 3001, a direct-facing area between the conductive plugs 310 can be effectively reduced, thereby effectively reducing the parasitic capacitance between the conductive plugs 310.

In an embodiment, the connection sections 3002 of adjacent conductive plugs 310 are at least partially staggered. In this case, the direct-facing area between the adjacent conductive plugs 310 can be further reduced, thereby further reducing the parasitic capacitance between the adjacent conductive plugs 310.

In an embodiment, the shape of the conductive plug 310 includes an L-shape and/or a U-shape.

Shapes of different conductive plugs 310 may be different or the same in the same semiconductor structure.

The connection section 3002 is connected to only one side of the recessed section 3001 when the conductive plug 310 is L-shaped. The connection section 3002 is connected to both sides of the recessed section 3001 when the conductive plug 310 is U-shaped.

In an embodiment, after the step of S20, the method includes the following step:

In the step of S40, multiple wiring structures 320 arranged in the first direction are formed on the surface of the dielectric layer 200, the wiring structure 320 extends in the second direction, and the wiring structure 320 is connected to the connection section 3002.

The multiple wiring structures 320 may be respectively connected to the connection sections 3002 of the conductive plugs 310 arranged in the first direction, so as to supply power to the conductive plugs respectively. Different wiring structures 320 may be connected to different conductive plugs 310. A conductive line 300 in the semiconductor structure may be jointly formed by one wiring structure 320 and a conductive plug 310 connected thereto. One signal may be transmitted by one conductive line 300.

In an embodiment, adjacent wiring structures 320 are at least partially staggered.

In this case, the adjacent wiring structures 320 are not exactly opposite to each other, thereby effectively reducing a parasitic capacitance between the adjacent wiring structures 320. In this case, both the parasitic capacitance between the conductive plugs 310 of adjacent conductive lines 300 and the parasitic capacitance between the wiring structures 320 are effectively reduced, so that mutual interference between signals transmitted by different conductive lines 300 is effectively reduced.

In an embodiment, after the step of S20, the method includes the following steps:

In the step of S311, referring to FIG. 7 and FIG. 9, an initial conductive plug 311 is formed in the contact hole 200a.

In the step of S312, referring to FIG. 10, a wiring material layer 321 is formed on surfaces of the initial conductive plug 311 and the dielectric layer 200.

In the step of S313, referring to FIG. 10, first patterned photoresist 400 is formed on the wiring material layer 321.

In the step of S314, referring to FIG. 11, the wiring material layer 321 and the initial conductive plug 311 are etched based on the first patterned photoresist 400 to form the multiple wiring structures 320 and the multiple conductive plugs 310.

In the step of S315, the first patterned photoresist 400 is removed.

In the step of S311, referring to FIG. 10, the contact hole 200a may be fully filled and covered by the initial conductive plug 311. The material of the initial conductive plug 311 may include but is not limited to tungsten.

A metal diffusion barrier layer (not shown) may be further formed between the initial conductive plug 311 and the inner wall of the contact hole 200a, so as to prevent metal in the metal plug from diffusing into the dielectric layer 200. Specifically, the material of the metal diffusion barrier layer may be, e.g., titanium nitride and/or titanium.

As an example, the step of S311 includes the following steps:

In the step of S3111, referring to FIG. 8, a conductive plug material layer 3111 is formed in the contact hole 200a and on the dielectric layer 200.

In the step of S3112, referring to FIG. 9, chemical mechanical polishing is performed on the conductive plug material layer 3111, the conductive plug material layer 3111 located on the surface of the dielectric layer is removed, and the conductive plug material layer 3111 in the contact hole is retained to form the initial conductive plug.

In the step of S3111, the conductive plug material layer 3111 (not shown) may be first formed in the contact hole 200a and on the dielectric layer 200 with physical vapor deposition (such as magnetron sputtering) or the like.

The conductive plug material layer 3111 may include a metal material layer, e.g., may include a metal tungsten material layer. In this case, before the step of S3111, a metal diffusion barrier material layer (not shown) may be further formed on the side wall and the bottom of the contact hole 200a and the surface of the dielectric layer 200. Then, in the step of S3111, a conductive plug material is formed on the surface of the metal diffusion barrier material layer, thereby preventing metal from diffusing into the dielectric layer 200. Afterwards, the metal diffusion barrier material layer on the upper surface of the dielectric layer 200 may be polished out when chemical mechanical polishing processing is performed on the conductive plug material, so as to form the metal diffusion barrier layer (not shown). The material of the metal diffusion barrier layer may be, e.g., titanium nitride and/or titanium.

In the step of S3112, the dielectric layer 200 may be utilized as a polishing stop layer, and chemical mechanical polishing processing may be performed on the conductive plug material layer 3111, so as to remove the conductive plug material layer 3111 located on the upper surface of the dielectric layer 200, thereby forming the initial conductive plug 311.

The upper surface of the dielectric layer 200 is made flush with the upper surface of the initial conductive plug 311 with a chemical mechanical polishing process.

In the step of S312, the wiring material layer 321 may be deposited on the whole surface by way of physical vapor deposition. The material of the wiring material layer 321 may include but is not limited to a metal material.

In the step of S313, referring to FIG. 10, photoresist may be first coated, and then exposed and developed to form the first patterned photoresist 400. The wiring material layer 321 is partially covered by the first patterned photoresist 400, and a covered region is configured to form the wiring structure 320. Moreover, the first patterned photoresist 400 is provided with an opening, and an opening exposure region is configured to form a region between the wiring structures 320 and the recessed section 3001 of the conductive plug 310.

In the step of S314, referring to FIG. 11, the wiring material layer 321 corresponding to the opening of the first patterned photoresist 400 is etched out after etching is performed based on the first patterned photoresist 400, so as to form the multiple wiring structures 320, thereby implementing the foregoing step S40.

Moreover, the initial conductive plug 311 covered by the wiring material layer 321 is partially etched and thinned, so as to form the multiple conductive plugs 310 including the connection sections 3002 and the recessed sections 3001. The initial conductive plug 311 on the recessed section 3001 is etched out. In this case, the foregoing step S30 can be implemented.

It may be understood that, the wiring material layer 321 and the initial conductive plug 311 may be etched under the same etching condition. The wiring material layer 321 and the initial conductive plug 311 may alternatively be etched under different etching conditions. In this case, an etching condition such as an etching gas may be changed and then the initial conductive plug 311 may be etched after the wiring material layer 321 is etched.

In addition, it may be understood that, a selective etching ratio of the wiring material layer 321 and the initial conductive plug 311 to the dielectric layer 200 may be relatively large. Therefore, the dielectric layer 200 may be hardly etched when the wiring material layer 321 and the initial conductive plug 311 are etched.

In the step of S315, the first patterned photoresist 400 may be removed after the conductive plug 310 is formed.

In this embodiment, the wiring structure 320 and the conductive plug 310 may be formed with a photolithography procedure, thereby effectively improving process efficiency. Certainly, in another embodiment, a manner of forming the wiring structure 320 and the conductive plug 310 may be different therewith.

For example, in some embodiments, after the step of S20, the method may further include the following steps:

In the step of S321, the initial conductive plug 311 is formed in the contact hole 200a.

In the step of S322, multiple initial wiring structures disposed at intervals are formed on the surfaces of the initial conductive plug 311 and the dielectric layer 200.

In the step of S323, second patterned photoresist is formed on the surface of the initial wiring structure.

In the step of S324, the initial wiring structure and the initial conductive plug 311 are etched based on the second patterned photoresist, so as to form the wiring structure 320 and the conductive plug.

In the step of S321, the contact hole 200a may be fully filled and covered by the initial conductive plug 311. The material of the initial conductive plug 311 may include but is not limited to tungsten.

A metal diffusion barrier layer (not shown) may be further formed between the initial conductive plug 311 and the inner wall of the contact hole 200a, so as to prevent metal in the metal plug from diffusing into the dielectric layer 200. Specifically, the material of the metal diffusion barrier layer may be, e.g., titanium nitride and/or titanium.

In the step of S322, another patterned dielectric layer (not shown) may be first formed on the surface of the dielectric layer 200 with processes such as deposition, photolithography, and etching. The patterned dielectric layer is provided with multiple long-strip-shaped openings. The initial conductive plug 311 and the surface of part of the dielectric layer 200 around the initial conductive plug 311 are exposed by the long-strip-shaped opening. Then, an initial wiring material layer is formed in each long-strip-shaped opening of the patterned dielectric layer and on the upper surface of the patterned dielectric layer. Then, the patterned dielectric layer is utilized as a polishing stop layer to perform chemical mechanical polishing processing on the initial wiring material layer, so as to form the multiple initial wiring structures.

Alternatively, the multiple initial wiring structures may be formed in another manner. For example, the initial wiring material layer may be first formed on the surfaces of the initial conductive plug 311 and the dielectric layer 200 with physical vapor deposition (such as magnetron sputtering) or the like. Then, patterned processing is performed on the initial wiring material layer with processes such as photolithography and etching, so as to form the multiple initial wiring structures.

In the step of S323, photoresist may be first coated, and then exposed and developed to form the second patterned photoresist. The initial wiring structure is partially covered by the second patterned photoresist. In addition, the second patterned photoresist is provided with an opening, and a partial section of the initial wiring structure may be exposed by the opening.

In the step of S324, the partial section of the initial wiring structure and a partial section of the initial conductive plug 311 may be etched out based on the second patterned photoresist, so as to form the wiring structure 320 and the conductive plug 310.

The initial wiring structure and the initial conductive plug 311 may be etched under the same etching condition. The initial wiring structure and the initial conductive plug 311 may alternatively be etched under different etching conditions. In this case, an etching condition such as an etching gas may be changed and then the initial conductive plug 311 may be etched after the initial wiring structure is etched.

In an embodiment, the base 100 includes a transistor structure 120. The transistor structure 120 includes a gate structure 121 and a source region 122 and a drain region 123 located on both sides of the gate structure 121. The dielectric layer 200 covers the transistor structure 120.

Moreover, referring to FIG. 6, the step of S20 includes the following step:

In the step of S21, multiple contact holes 200a extending to the source region 122 and/or the drain region 123 of the transistor structure 120 are formed in the dielectric layer 200.

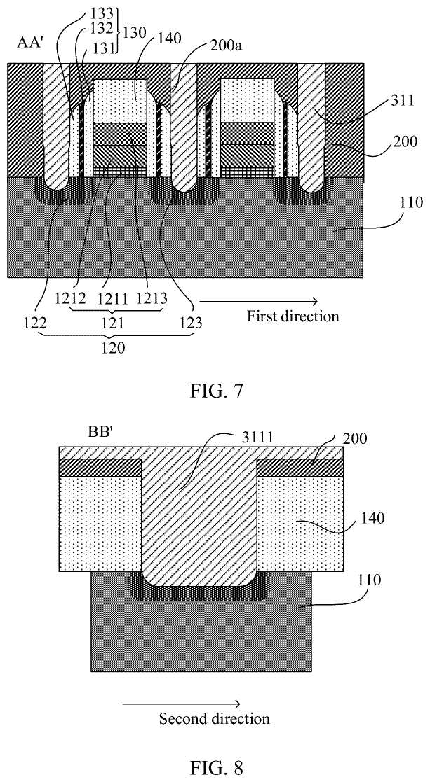

As an example, in this case, in the step of S314, referring to FIG. 2 or FIG. 4, the initial conductive plug 311 may be etched to below the upper surface of the gate structure 121 when etching is performed based on the first patterned photoresist 400, thereby reducing a parasitic capacitance between the gate structure 121 and the conductive plug 310, and further ensuring device performance.

In an embodiment, the step of S314 includes the following step:

In the step of S3141, the wiring material layer 321 and the initial conductive plug 311 are etched based on the first patterned photoresist 400 to form a first wiring 320a, a second wiring 320b, and a third wiring 320c sequentially arranged in the first direction, and form an L-shaped first plug 310a under the first wiring 320a, form a U-shaped second plug 310b under the second wiring 320b, and form an L-shaped third plug 310c under the third wiring 320c.

In this case, in the second direction, the second plug 310b is connected to the second wirings 320b at both ends, the first plug 310a is connected to the first wiring 320a at one end, and the third plug 310c is connected to the third wiring 320c at one end.

Moreover, as an example, a contact area S1 between the first plug 310a and the first wiring 320a connected thereto at one end may be set to be equal to a contact area S2 between the second plug 310b and the second wiring 320b connected thereto at both ends.

In this case, R1 is the same as R2 assuming that a contact resistance between the first plug 310a and the first wiring 320a connected thereto at one end is R1, and a contact resistance between the second plug 310b and the second wiring 320b connected thereto at both ends is R2.

Alternatively, as an example, a contact area S3 between the third plug 310c and the third wiring 320c connected thereto at one end may be set to be equal to a contact area S2 between the second plug 310b and the second wiring 320b connected thereto at both ends.

In this case, R3 is the same as R2 assuming that a contact resistance between the third plug 310c and the third wiring 320c connected thereto at one end is R3.

Certainly, S1, S2, and S3 may be set to be the same. In this case, synchronization performance of signals transmitted by the wiring structures 320 can be improved.

Alternatively, in some cases, a difference between any two of S1, S2, and S3 may be set to be less than a preset difference, so that S1 and S2 are close to S3, and synchronization performance of the signals transmitted by the wiring structures 320 is relatively good. The preset difference may be set according to an actual requirement.

It should be understood that, although the steps in the flowchart of FIG. 1 are sequentially displayed according to indications of the arrows, these steps are not necessarily sequentially performed according to the indications of the arrows. Unless expressly stated in the specification, these steps are not performed in a strict order, and these steps may be performed in another order. In addition, at least some steps in FIG. 1 may include multiple steps or multiple phases. These steps or phases are not necessarily performed and completed at the same moment, but may be performed at different moments. These steps or phases are not necessarily performed sequentially, but may be performed in turn or alternately with another step or at least some of the steps or phases in the another step.

The technical features in the foregoing embodiments may be combined arbitrarily. For brevity of description, not all possible combinations of these technical features in the foregoing embodiments are described. However, as long as these combinations of technical features are not contradictory, they should all be considered within the scope described in the specification

The foregoing embodiments represent only several implementations of the present disclosure, and descriptions thereof are relatively specific and detailed, but should not be construed as limitations on the patent scope of this application. It should be noted that, a person of ordinary skill in the art can further make several variations and improvements without departing from the concept of the present disclosure, all of which shall fall within the protection scope of the present disclosure. Therefore, the patent protection scope of the present disclosure shall be subject to the appended claims.

What is claimed is:

1. A semiconductor structure, comprising:
a base;
a dielectric layer being located on the base and internally provided with a plurality of contact holes arranged in a first direction; and
a plurality of conductive plugs arranged in the first direction, the conductive plug being located in the contact hole and comprising a connection section and a recessed section, the connection section being configured for conductive connection, the recessed section being connected to the connection section in a second direction and recessed downwards relative to the connection section, and the second direction intersecting the first direction.

2. The semiconductor structure according to claim 1, wherein connection sections of adjacent ones of the conductive plugs are at least partially staggered.

3. The semiconductor structure according to claim 1, wherein
the base comprises a transistor structure, the transistor structure comprising a gate structure and a source region and a drain region located on both sides of the gate structure, the dielectric layer covering the transistor structure, and the contact holes extending to the source region and/or the drain region of the transistor structure; and
the recessed section is recessed downwards to a height less than a height of the gate structure.

4. The semiconductor structure according to claim 1, wherein a shape of the conductive plug comprises an L-shape and/or a U-shape.

5. The semiconductor structure according to claim 1, wherein
the semiconductor structure further comprises a plurality of wiring structures arranged in the first direction,
the wiring structure being located on a surface of the dielectric layer and extending in the second direction, and the wiring structure being connected to the connection section.

6. The semiconductor structure according to claim 5, wherein adjacent ones of the wiring structures are at least partially staggered.

7. The semiconductor structure according to claim 6, wherein
the wiring structure comprises a first wiring, a second wiring, and a third wiring sequentially arranged in the first direction, and the conductive plug comprises an L-shaped first plug, a U-shaped second plug, and an L-shaped third plug sequentially arranged in the first direction, and
in the second direction, the second plug is connected to the second wirings at both ends, the first plug is connected to the first wiring at one end, and the third plug is connected to the third wiring at one end.

8. The semiconductor structure according to claim 7, wherein the first plug and the third plug are connected to the wiring structure at opposite ends.

9. The semiconductor structure according to claim 7, wherein
a contact area between the first plug and the first wiring connected thereto at one end is equal to a contact area between the second plug and the second wiring connected thereto at both ends.

10. The semiconductor structure according to claim 7, wherein
a contact area between the third plug and the third wiring connected thereto at one end is equal to a contact area between the second plug and the second wiring connected thereto at both ends.

11. A preparation method for a semiconductor structure, comprising:
providing a base, a dielectric layer being formed on the base;
forming a plurality of contact holes arranged in a first direction in the dielectric layer; and
forming a conductive plug in each of the contact holes, the conductive plug comprising a connection section and a recessed section, the connection section being configured for conductive connection, the recessed section being connected to the connection section in a second direction and recessed downwards relative to the connection section, and the second direction intersecting the first direction.

12. The preparation method for a semiconductor structure according to claim 11, wherein the connection sections of adjacent ones of the conductive plugs are at least partially staggered.

13. The preparation method for a semiconductor structure according to claim 11, wherein the conductive plug comprises an L-shaped plug and/or a U-shaped plug.

14. The preparation method for a semiconductor structure according to claim 11, after the forming a plurality of contact holes arranged in a first direction in the dielectric layer, comprising:
forming, on a surface of the dielectric layer, a plurality of wiring structures arranged in the first direction, the wiring structure extending in the second direction, and the wiring structure being connected to the connection section.

15. The preparation method for a semiconductor structure according to claim 14, wherein adjacent ones of the wiring structures are at least partially staggered.

16. The preparation method for a semiconductor structure according to claim 14, after the forming a plurality of contact holes arranged in a first direction in the dielectric layer, comprising:
forming an initial conductive plug in the contact hole;
forming a wiring material layer on surfaces of the initial conductive plug and the dielectric layer;
forming first patterned photoresist on the wiring material layer;
etching the wiring material layer and the initial conductive plug based on the first patterned photoresist to form the plurality of wiring structures and the plurality of conductive plugs; and
removing the first patterned photoresist.

17. The preparation method for a semiconductor structure according to claim 16, wherein
the base comprises a transistor structure, the transistor structure comprising a gate structure and a source region and a drain region located on both sides of the gate structure, and the dielectric layer covering the transistor structure, and
the forming a plurality of contact holes arranged in a first direction in the dielectric layer comprises:
forming, in the dielectric layer, a plurality of contact holes extending to the source region and/or the drain region of the transistor structure.

18. The preparation method for a semiconductor structure according to claim 17, wherein the initial conductive plug is etched to below an upper surface of the gate structure when the wiring material layer and the initial conductive plug are etched based on the first patterned photoresist.

19. The preparation method for a semiconductor structure according to claim 16, wherein the etching the wiring material layer and the initial conductive plug based on the first patterned photoresist to form the plurality of wiring structures and the plurality of conductive plugs comprises:
etching the wiring material layer and the initial conductive plug based on the first patterned photoresist to form a first wiring, a second wiring, and a third wiring sequentially arranged in the first direction, forming an L-shaped first plug under the first wiring, forming a U-shaped second plug under the second wiring, and forming an L-shaped third plug under the third wiring.

20. The preparation method for a semiconductor structure according to claim 16, wherein
the forming an initial conductive plug in the contact hole comprises:
forming a conductive plug material layer in the contact hole and on the dielectric layer; and
performing chemical mechanical polishing on the conductive plug material layer, removing the conductive plug material layer located on the surface of the dielectric layer, and retaining the conductive plug material layer in the contact hole to form the initial conductive plug.
